(19) United States
(12) Patent Application Publication
(10) Pub. No.: US 2025/0181793 A1
(43) Pub. Date: Jun. 5, 2025

(54) DYNAMIC SLOTTING

(71) Applicant: CreateASoft, Inc., Aurora, IL (US)

(72) Inventor: Hosni I. Adra, Naperville, IL (US)

(21) Appl. No.: 18/525,419

(22) Filed: Nov. 30, 2023

(51) Int. Cl. G06F 30/20; G06Q 10/04; G06Q 10/087

(52) U.S. Cl. CPC G06F 30/20; G06Q 10/04; G06Q 10/087

(57) ABSTRACT

A facility for determining re-slotting items and dispatching entities for picking operations is described. At a first time, the facility receives an indication of orders that indicate a time at which at least one item is scheduled to depart from a complex. The facility generates pick sequences from the orders and obtains simulation data that includes predicted states of the complex by applying the pick sequences to a digital twin simulation of a complex. The facility identified alternative storage locations for items included in the pick sequences based on the predicted states of the complex. At a second time after the first time, the facility receives data indicating a current state of the complex and identifies a pick sequence based on the alternative storage locations, current state of the complex, and the generated pick sequences. The facility dispatches entities to execute the identified pick sequence.

### BACKGROUND

Complexes in which items are stored and retrieved—such as factories, fulfillment centers, warehouses, etc.—typically have designated storage areas for items, and items are picked for shipping based on customer demand. Entities that perform the picking operations in a complex include: people, such as workers in the complex, customers, visitors, etc.; vehicles, such as automated vehicles, for example, an Automated Guided Vehicle (an AGV), vehicles operated by a person, etc.; and other entities that may handle an item in a complex.

### BRIEF DESCRIPTION OF THE DRAWINGS

FIG. 1 is a block diagram showing some of the components typically incorporated in at least some of the computer systems and other devices on which the facility operates.

FIG. 2 is a complex diagram showing a sample state of a simulated complex which is displayed by the facility in some embodiments.

FIG. 3 is a flow diagram of a process to identify an alternative storage location for re-slotting an item used by the facility in some embodiments.

FIG. 4 is a table diagram depicting a pick sequence data table used by the facility in some embodiments.

FIG. 5 is a process to dispatch entities to pick items used by the facility in some embodiments.

FIG. 6 is a flow diagram of a process to identify congestion within a complex used by the facility in some embodiments.

FIG. 7 is a flow diagram of a process to train a machine learning model to output a projected cost of SKU for picking an item from a location used by the facility in some embodiments.

FIG. 8 is a flow diagram of a process to use a nesting coefficient to generate an indication of how an item should be stored in a storage location used by the facility in some embodiments.

FIG. 9 is a flow diagram of a process to use a nesting coefficient to generate an indication of how an item should be placed in a picking container used by the facility in some embodiments.

### DETAILED DESCRIPTION

The inventor has recognized that it would be of great benefit to simulation engineers, managers of simulated complexes, etc., to use a simulation of the complex to dynamically adjust the re-slotting and picking processes for items departing from a complex. The simulation is used to identify locations for re-slotting items based on orders received by the complex in order to optimize the picking process for those orders. The inventor has also determined that it would be beneficial to use the simulation to predict how entities will move within the complex as they re-slot items, pick items, put-away items, etc. in order to identify when entities should begin a pick sequence.

The inventor has recognized a variety of disadvantages of current simulation and warehouse management software and practices for performing re-slotting and picking operations. Typical simulation and warehouse management software re-slot items based on their “velocity,” such that items that are more likely to be included in orders are moved from their initial storage location to storage locations near the staging area or in a common location. This results in high velocity items being clustered closely together and results in a greater amount of congestion in that area because those items are the most likely to be picked and therefore also the most likely to have entities trying to pick them. Additionally, these systems do not take into account congestion throughout the complex when releasing entities to pick items or perform other operations within the complex. Instead, conventional systems release entities in “waves” such that a group of entities is released each with their own pick sequence. However, because the pick sequences are typically for the same or similar orders, the entities must pick items from the same locations, which also results in congestion in the complex. The high congestion results in increased idle time for entities performing picking, re-slotting, put-away, and other processes, such as robots, AGV's, and other entities, and thus causes resource waste, such as, in the case of entities that use electronics, wasted power while waiting for an item to be able to be picked, processor cycles spent on idling, etc. Furthermore, these systems do not accurately account for nesting items correctly, which reduce the maximum storage density of the complex.

As a result of these disadvantages, items in the complex are re-slotted and pickers are released in a manner that causes congestion within the complex and resources and entities within the complex are unable to efficiently perform their tasks. Additionally, typical simulation and warehouse management systems do not properly account for items that are able to nest within, on top of, etc., each other. Furthermore, typical simulation and warehouse management systems are unable to take into account the behavior of entities when performing re-slotting, picking, put-away, and other tasks or operations within the complex.

In response to recognizing these disadvantages, the inventor has conceived and reduced to practice a software and/or hardware facility for dynamically controlling re-slotting and picking processes (“the facility”). By using a digital twin simulation model of the complex, the facility is able to determine storage areas for items scheduled to be picked in a way that more fully accounts for the full cost of re-slotting and picking operations. The facility additionally causes these items to be placed in the determined storage areas by causing an entity to move the items to the designated storage area. Furthermore, the facility identifies pick sequences for entities based on the current state of the complex to account for and prevent congestion within the complex when entities are released to perform picking operations.

The facility operates a digital twin simulation model of a complex to determine a new or alternative storage location for an item to optimize picking processes and to schedule and release pickers to perform picking operations. In some embodiments, operating the digital twin simulation model includes obtaining one or more incoming orders, one or more outgoing orders, or some combination thereof. An incoming order includes one or more of: an indication of one or more items presently arriving at the complex or an indication of a future time at which one or more items will arrive at the complex. An outgoing order includes one or more of: an indication of one or more items presently departing from the complex or an indication of a future time at which one or more items will depart from the complex. The facility generates one or more “pick sequences” from each outgoing order that include instructions for a picker regarding one or more of: which items should be picked, the quantity of each item picked, the time at which the items are to be picked, the order for picking the items, any entities necessary to assist in picking items, or other information relevant to picking items for an order. In some embodiments, the facility determines a storage location for re-slotting the item based on one or more factors, such as: a size or dimension of the item; a volume of the item; a nesting factor of the item; a weight of the item; a crushability factor of the item; a seasonality of the item; an indication of the quantity of the item in the complex; an indication of handling constraints for the item, such as an indication of whether the item can be moved multiple times, whether special equipment is needed for the item, an indication of whether the item needs to be stored in a certain type of storage area, or other handling constraints; an indication of whether multiple items of the same type are included in the order; an indication of whether multiple items of the same type can be handled together; an indication of the current state of the digital twin simulation model; an indication of one or more congestion factors; an indication of the number of entities available to handle the item; an indication of the efficiency of at least one of the entities; an indication of the constraints of the storage media of the item, such as a weight limit for the storage media, a volume limit of the storage media, a direction that the storage media should face, or other constraints of storage media; an indication of an orientation requirement of the item when stored; an indication of the cost factors of at least one handling constraint, such as a cost of using an entity to handle the item; an indication of the cost factors of at least one storage constraint, such as a cost to store the item for a selected period of time; a controlled item requirement, such as an indication that the item is to be stored in a controlled area, such as a temperature-controlled area, a humidity-controlled area, a security-controlled area, etc.; a predicted need for the item at a future time; information about existing outgoing orders for the item; predicted future outgoing orders for the item; a grab factor, such as a quantity of the item that can be picked up at the same time by an entity; or other factors used to determine a storage area for an item. In some embodiments, the facility determines the storage location for the item based on a prediction of the state of the complex at a time during which the items included in the order will be picked. The facility generates a prediction of the state of the complex based on at least the digital twin simulation model and incoming orders, outgoing orders, or some combination thereof.

In some embodiments, the facility determines a nesting factor of the item as part of determining a storage location for the item. The nesting factor includes an indication of the orientation of the item when stored or placed in a container associated with an entity, such as an indication of the orientation of the item in the x, y, and z planes. Basically need to reconfigure this for re-slotting/picking In some embodiments, the nesting factor includes a nesting coefficient that indicates how nested items affect the total storage space. For example, the nesting coefficient of a cup may indicate that when two cups are nested together the total height of the cup is less than the sum of the height of each of the two cups added together. In some embodiments, the facility identifies one or more nesting constraints of the item, such as whether the item rolls, a maximum or minimum number of rows or columns for storing the item, or other factors that indicate how the item will interact with other items when stored near or on top of the other items. In some embodiments, the facility generates a visual indication of how the item should be stored based on the nesting factor and the current state of the digital twin simulation model. In some embodiments, the facility generates the visual indication based on the dimensions of the storage location, the dimensions of the items currently stored in the location, the dimensions of the item, and the nesting factor to determine whether the item can be stored in the storage location.

A factor of the congestion, or “traffic,” around storage areas is determined based on one or more orders received by the facility. The facility determines the factor of congestion by applying the one or more orders to the digital twin simulation model to identify where and when entities will be picking items, putting away items, or performing other operations within the complex. In some embodiments, the facility generates one or more heat maps, traffic maps, congestion maps, etc., that indicate the amount of traffic throughout the complex based on the application of the one or more orders to the digital twin simulation model. In some embodiments, the facility collects data regarding the change in the congestion factor throughout the complex over time. In such embodiments, the facility may use the data regarding the change in the congestion factor over time and an indication of future orders to predict times at which one or more locations throughout the complex will be heavily congested.

In some embodiments, the facility trains an artificial intelligence or machine learning model (a “machine learning model”) to determine a storage location for an item. The facility trains the machine learning model based on historical data of where items are stored and the “cost of SKU” for each item. In some embodiments, the historical data additionally includes a number of orders per hour fulfilled by the complex, a lead time for orders at the complex, or some combination thereof. A cost of SKU is a cost calculated based on one or more of: one or more storage requirements for the item; the number of interactions with the item by one or more entities needed to store or stage the item; an indication of the amount of time needed to adjust a pallet or other storage container containing the item; an indication of whether the item can be stored on a rack, on the floor, or on another storage implement; a cost associated with one or more entities that interact with the item; a cost to store the item for a selected period of time; or other costs associated with storing the item. In some embodiments, the facility re-trains the machine learning periodically to enhance the accuracy of the machine learning model, to ensure the machine learning model takes into account seasonality of the items, or some combination thereof. In some embodiments, the machine learning model outputs a cost of SKU for storing the item at a location. In some embodiments, the facility applies one or more of: a description of the item, a location for storing the item; a number of picks at the location; an elevation of the location; a depth of the location; a factor of the amount of time needed to pick the item; a time of day at which the item is to be stored; an indication of the number of similar items that can be picked at the same time; or other factors related to storing the item to the machine learning model as inputs. In some embodiments, the cost of SKU takes into account the cost for an entity to pick, store, re-slot, or perform other operations to or for an item. In such embodiments, the facility may train a separate machine learning model that outputs an indication of an extent to which one or more entities contribute to the cost of SKU based on their behavior when performing operations with relation to items, areas within the complex, etc. The facility may apply the output of the separate machine learning model to the machine learning model that outputs the cost of SKU. In some embodiments, the facility uses the separate machine learning model to select an entity to perform a pick sequence.

The facility determines one or more alternative storage locations for an item that is already stored at a complex based on one or more outgoing orders. In some embodiments, the facility identifies the alternative locations based on a cost of SKU for storing the items at one or more locations and a predicted state of the complex. In some embodiments, the cost of SKU of the alternate storage locations is calculated based on the current state of the digital twin simulation model. In some embodiments, the predicted state of the complex is obtained by applying one or more pick sequences generated from the outgoing order to a digital twin simulation model of the complex.

In an example embodiment, the facility receives one or more outgoing orders that indicate that a plurality of items will depart from the complex at one or more future times. The facility generates pick sequences based on the outgoing orders and applies the pick sequences to a digital twin simulation model to obtain simulation data indicating a forecasted state of the complex at the future times and a factor of the congestion around storage areas within the complex at the future times. The facility identifies attributes of items in the complex, including a nesting factor of the item, and uses the attributes, the forecasted state of the complex, and the pick sequences to identify one or more alternative storage locations for items in the complex. The facility causes entities to move the items to the alternative storage locations. At a later time, the facility receives data indicating a current state of the complex, including a factor of congestion at one or more areas within the complex. The facility uses the data indicating the current state of the complex and the generated pick sequences to select a pick sequence and dispatch one or more entities to execute the pick sequence.

By performing in some or all of the ways described above, the facility is able to quickly and reliably determine alternative storage locations for items to reduce congestion within a complex, and to select and cause entities to execute pick sequences. Also, the facility improves the functioning of computer or other hardware, such as by reducing the dynamic display area, processing, storage, and/or data transmission resources needed to perform a certain task, thereby enabling the task to be permitted by less capable, capacious, and/or expensive hardware devices, and/or be performed with lesser latency, and/or preserving more of the conserved resources for use in performing other tasks. For example, the facility is able to reduce idle time for entities executing pick sequences by identifying alternative storage locations for items that reduce congestion within the complex. Additionally, the facility is able to ensure that entities are released to perform pick sequences in a manner that prevents the entities from being clustered within a small number of areas within the complex, and thus cause congestion. In this example, computing systems that manage or are used by entities expend fewer computing resources, such as memory, processing power, and electrical power, in idle states because the amount of time entities need to take to wait for other entities to complete their tasks before picking an item is reduced in comparison to entities in a complex with conventional systems.

Furthermore, the processes, data, and models used by the facility are an improvement in the technical field of simulation and warehouse management software. The processes, data, and models are able to determine re-slotted locations for items to reduce the amount of congestion in the complex in a way that is beyond the capabilities of typical simulation and management software. The processes, data, and models are also able to select and release pick sequences in a way that is also beyond the capabilities of current simulation and management software.

Additionally, for at least some of the domains and scenarios discussed herein, the processes described herein as being performed automatically by a computing system cannot practically be performed in the human mind, for reasons that include that the starting data, intermediate state(s), and ending data are too voluminous and/or poorly organized for human access and processing, and/or are a form not perceivable and/or expressible by the human mind; the involved data manipulation operations and/or subprocesses are too complex, and/or too different from typical human mental operations; required response times are too short to be satisfied by human performance; etc.

In the present application, references to “optimizing,” “optimization,” “optimize,” etc. means improving or seeking to improve the efficiency of aspects of an entity, a group of entities, a complex, operations within the complex, etc. As a result, optimization can occur even if the facility fails to identify a more efficient storage location, pick sequence, entity, etc., or the most efficient possible storage location, pick sequence, entity, etc.

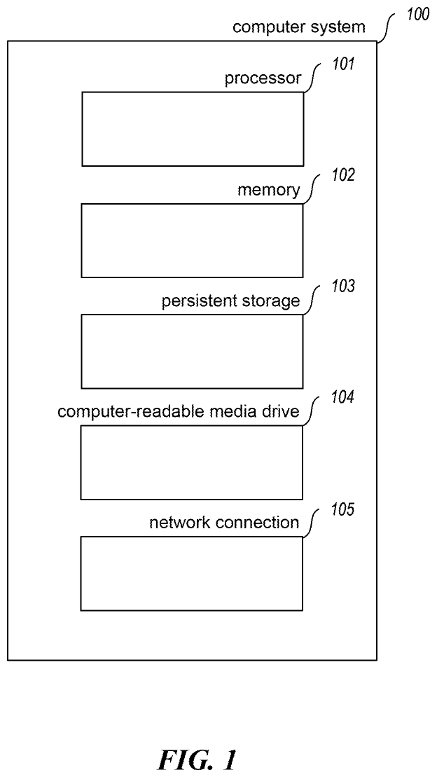

FIG. 1 is a block diagram showing some of the components typically incorporated in at least some of the computer systems and other devices on which the facility operates. In various embodiments, these computer systems and other devices 100 can include server computer systems, cloud computing platforms or virtual machines in other configurations, desktop computer systems, laptop computer systems, netbooks, mobile phones, personal digital assistants, televisions, cameras, automobile computers, electronic media players, etc. In various embodiments, the computer systems and devices include zero or more of each of the following: a processor 101 for executing computer programs and/or training or applying machine learning models, such as a CPU, GPU, TPU, NNP, FPGA, or ASIC; a computer memory 102 for storing programs and data while they are being used, including the facility and associated data, an operating system including a kernel, and device drivers; a persistent storage device 103, such as a hard drive or flash drive for persistently storing programs and data; a computer-readable media drive 104, such as a floppy, CD-ROM, or DVD drive, for reading programs and data stored on a computer-readable medium; and a network connection 105 for connecting the computer system to other computer systems to send and/or receive data, such as via the Internet or another network and its networking hardware, such as switches, routers, repeaters, electrical cables and optical fibers, light emitters and receivers, radio transmitters and receivers, and the like. None of the components shown in FIG. 1 and discussed above constitutes a data signal per se. While computer systems configured as described above are typically used to support the operation of the facility, those skilled in the art will appreciate that the facility may be implemented using devices of various types and configurations, and having various components.

Those skilled in the art will appreciate that the acts shown in the flow diagrams discussed below may be altered in a variety of ways. For example, the order of the acts may be rearranged; some acts may be performed in parallel; shown acts may be omitted, or other acts may be included; a shown act may be divided into subacts, or multiple shown acts may be combined into a single act, etc.

Furthermore, while the table diagrams discussed below show a table whose contents and organization are designed to make them more comprehensible by a human reader, those skilled in the art will appreciate that actual data structures used by the facility to store this information may differ from the table shown, in that they, for example, may be organized in a different manner; may contain more or less information than shown; may be compressed, encrypted, and/or indexed; may contain a much larger number of rows than shown, etc.

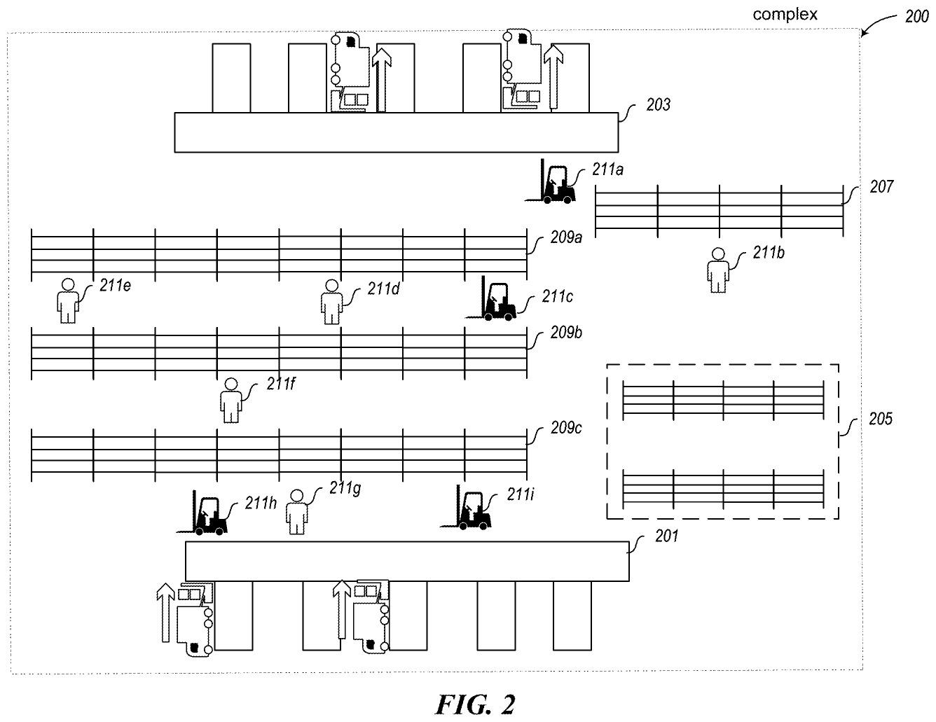

FIG. 2 is a complex diagram showing a sample state of a simulated complex 200 which is displayed by the facility in some embodiments. The sample simulated complex 200 is generated by the facility to represent a complex, such as a factory, fulfillment center, medical complex, or other complex. The simulated complex 200 is a “digital twin” of the complex that it represents, such that it is able to simulate the current state of the complex, a past state of the complex, or a predicted future state of the complex. In some embodiments, the facility generates the simulated complex 200 based on a definition of a simulation model, such as a simulation model provided via user input. In some embodiments, the facility generates the simulation model based on user input. In some embodiments, the definition of a simulation model includes one or more of: information describing the layout of the complex, one or more entities in the simulation model, one or more objects or items that may be received at or may depart from the complex, one or more orders for items that have been or will be received at or may depart from the complex, one or more items or objects that are currently stored in the complex, or other data that may be used to create a digital twin simulation model of a complex.

The simulated complex 200 includes: a receiving area 201; a shipping area 203; a specialized storage area 205; a picking rack 207 (also referred to as a “staging area”); one or more storage racks 209a, 209b, and 209c (collectively “storage racks 209”); and one or more entities 211a, 211b, 211c, 211d, 211e, 211f, 211g, 211h, and 211i (collectively “entities 211”). The receiving area 201 is an area within which items associated with incoming orders arrive, and from which items are put away by an entity, such as one or more of the entities 211a-211i. The shipping area 203 is an area within which items associated with outgoing orders are loaded onto one or more vehicles for transportation away from the complex 200.

The specialized storage area 205 is a controlled storage area that is able to provide a controlled environment for storing one or more items within the complex. For example, the specialized storage area 205 may be a temperature-controlled area, a humidity-controlled area, a security-controlled area, etc. The picking rack 207 is a storage rack that stores items that have been picked to be shipped out through the shipping area 203. For example, an outgoing order may include one or more items that are picked by one or more entities and stored on the picking rack 207 until a vehicle that is able to transport the items arrives and is loaded. The storage racks 209 are each storage racks that hold items that are put away after they arrive at the complex via the receiving area 201 or after the alternative storage locations are determined in order to re-slot the items before a picking operation. Although FIG. 2 depicts racks for storage within the complex 200, embodiments are not so limited, and the complex 200 may include storage areas or containers other than storage racks, such as, for example, an automated storage and retrieval system.

The entities 211 are each entities that interact with items during put-away and picking processes, such as human workers, manually driven forklifts or other vehicles, autonomous vehicles, etc. The entities receive instructions regarding where to store items, how to store the items, an orientation for storing the items, a route to take to the storage area, which items should be picked, whether items should be moved from one storage location to another, etc., and carry out those operations when items in an order arrive at or are to depart from the complex 200. In some embodiments, the entities receive such instructions via a computing system or other hardware device accessible to the entity. In some embodiments, entities complete one or more operations, such as picking, re-slotting, put-away, etc., in tandem with other entities, such as, for example: a robot passing items to another robot, an AGV being loaded by a worker, a worker operating a forklift being aided by another worker, etc.

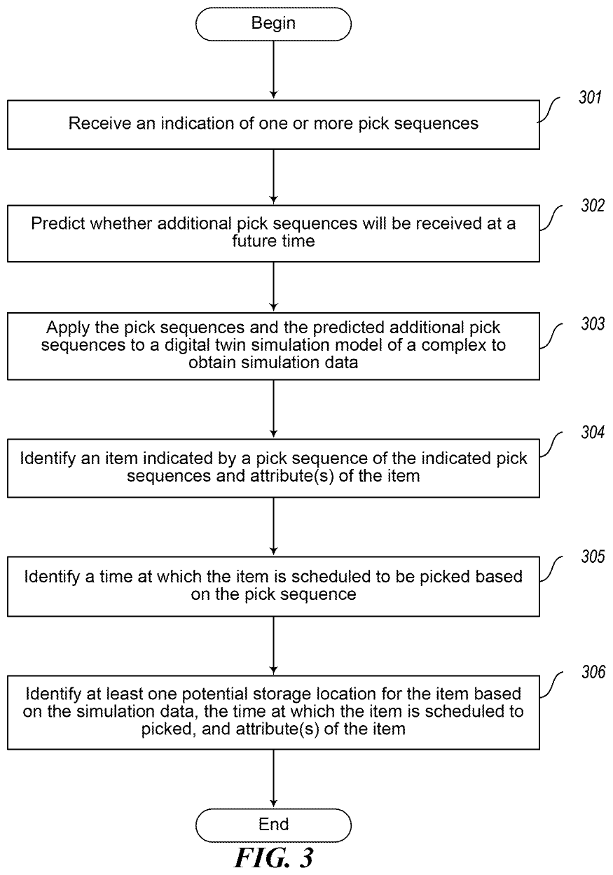

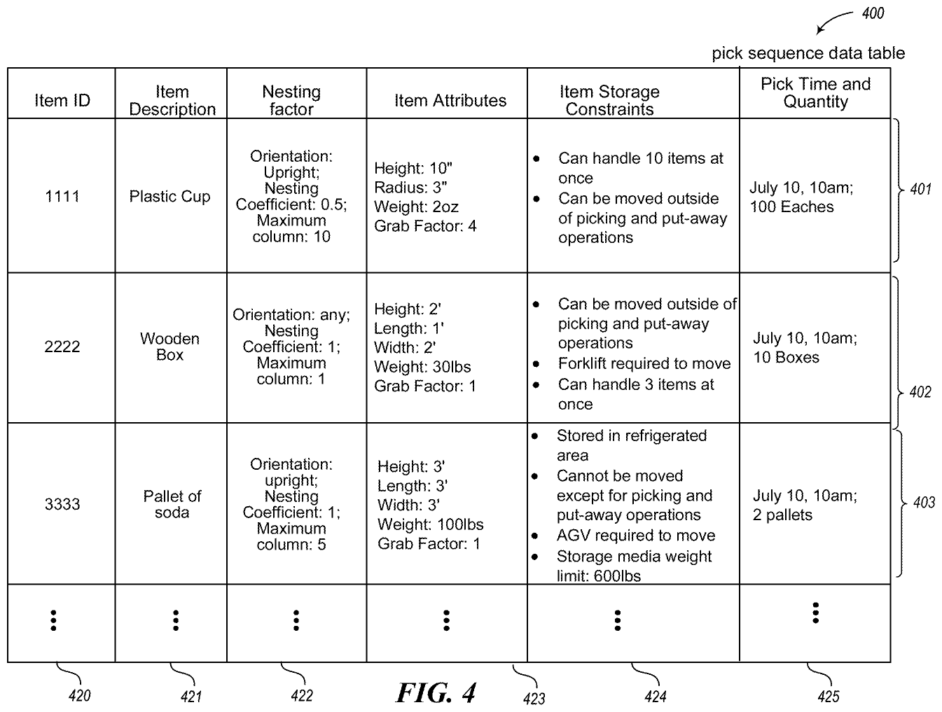

FIG. 3 is a flow diagram of a process to identify an alternative storage location for re-slotting an item used by the facility in some embodiments. First, at act 301, the facility receives an indication of one or more pick sequences. In some embodiments, the facility generates the pick sequences from one or more orders, such as outgoing orders. In some embodiments, the pick sequences include information describing one or more items, one or more attributes of the items, one or more times at which the items are scheduled to depart from the complex, an order for picking the one or more items, a number of each item to be picked, or other information related to a pick sequence. In some embodiments, pick sequence is stored in a pick sequence data table, such as the pick sequence data table 400 described below in connection with FIG. 4.

FIG. 4 is a table diagram depicting a pick sequence data table 400 used by the facility in some embodiments. The pick sequence data table 400 includes an item id column 420, an item description column 421, a nesting factor column 422, an item attributes column 423, an item storage constraints column 424, and a pick time and quantity column 425. Although the pick sequence data table 400 depicts many attributes of items included in a pick sequence, embodiments are not so limited, and the pick sequence data table 400 may include any item attribute that is related to the factors used by the facility to identify a storage location for an item or to determine whether an entity should be caused to execute the pick sequence. The item id column 420 includes information identifying an item included in a pick sequence represented by the pick sequence data table 400. The item description column 421 includes information indicating a description of the item identified in the item id column 420.

The nesting factor column 422 includes information indicating one or more nesting constraints for the item identified in the item id column 420. For example, row 401 indicates that item “1111” should be stored upright, that ten of the same item can be stacked, and that the nesting coefficient is 0.5. In another example, row 402 indicates that item “2222” can be stored in any orientation, can be stacked up to five items high, and has a nesting coefficient of 1.

The item attributes column 423 includes information indicating one or more attributes of the item identified in the item id column 420, such as, for example, a size of the item, a weight of the item, a color of the item, grab factor for the item, or other attributes of the item. For example, row 403 indicates that item “3333” has a height, width, and length of three feet, weighs 100 pounds, and can be grabbed by an entity one at a time. As another example, row 401 indicates that item “1111” is ten inches high, has a radius of three inches, weighs two ounces, and can be grabbed by an entity four at a time.

The item storage constraints column 424 includes information identifying storage constraints for the item identified in the item id column 420, such as a maximum number of items that an entity can handle at one time, whether the item is able to be moved to another storage location, a weight limit of the storage media of the item, whether special equipment is required to handle the item, a type of controlled area for storing the item, and other attributes related to storing the item. For example, row 401 indicates that an entity can handle up to ten of item “1111” at one time and that the item can be moved to other storage areas outside of picking and put-away operations, such as to make room for other items at a storage location. Row 403 indicates that item “3333” is to be stored in a refrigerated area, that the item cannot be moved outside of picking and put-away operations, that the item's storage medium has a weight limit of six hundred pounds, and that an AGV is required to move the item. Row 402 indicates that item “2222” can be moved outside of picking and put-away operations, that a forklift is required to move the item, and that three of the item can be handled by a single entity.

The pick time and quantity column 425 includes information indicating a time by which the item identified in the item id column 420 is to be picked and the quantity of items that are picked. For example, rows 401 and 402 indicate that ten boxes of item “2222” and one hundred individual items (“eaches”) of item “1111” are to be picked by 10:00 am on July 10 and row 403 indicates that two pallets of item “3333” are to be picked at 10:00 am on July 10.

In some embodiments, the pick sequence data table includes additional data regarding how the items in the pick sequence are to be picked. For example: whether the items are picked by eaches, bunches, pallets, boxes, etc.; an amount of time the items can remain in the staging area; the size, weight, and crushability factor of the items; the size of the container used by the entity to carry the item, such as a box, bin, tote, pallet, etc.; an order in which the items must be picked; whether multiple locations must be visited to pick the quantity of the item indicated by the pick sequence; a location of the item; whether the item can destroy or otherwise damage other items in the pick sequence; or other information relevant to a pick sequence and the picking process. For example, the pick sequence may include liquid detergent, cream cheese, and bread. Because liquid detergent is heavy, and because leaking detergent may irreparably damage the cheese and bread, the pick sequence may include instructions to pick the liquid detergent first. The pick sequence may also include instructions to pick the cream cheese after the liquid detergent in order to ensure that the cream cheese does not crush the bread.

Returning to FIG. 3, at act 302, the facility predicts whether additional pick sequences will be received at a future time. In some embodiments, the facility predicts whether additional pick sequences will be received based on historical data regarding the number of pick sequences that are executed at the complex, the number of items that typically are shipped out of the complex, or some combination thereof. In such embodiments, the facility may also generate the predicted pick sequences based on the historical data. For example, if the complex typically has one hundred pick sequences on Mondays, and that twenty percent of the pick sequences are received once the picking process has begun on Mondays. In this example, if the facility has eighty pick sequences at the beginning of the day on Monday, it may determine that twenty more pick sequences will be received, and generate predictions of what those pick sequences may be. In some embodiments, the facility performs act 302 by using an artificial intelligence or machine learning model trained based on the historical data to predict whether additional orders or pick sequences will be received by the complex.

At act 303, the facility applies the pick sequences and the predicted additional pick sequences to a digital twin simulation model of a complex, such as the simulated complex 200 described above in connection with FIG. 2, to obtain simulation data. The simulation data includes one or more predicted states of the complex as pick sequences are executed. In some embodiments, the simulation data includes an indication of congestion, or “traffic,” within the complex caused by put-away and picking operations that are scheduled to occur during the time at which the orders are scheduled to arrive, during the time at which the put-away and picking operations for items included in the orders are being performed, or other operations related to the functioning of the complex are being performed. In some embodiments, a predicted state of the complex includes an indication of the storage capacity of one or more storage areas within the complex.

In some embodiments, the pick sequences applied to the digital twin simulation model are generated from outgoing orders. In some embodiments, at act 303, the facility additionally applies incoming orders to the digital twin simulation model. In some embodiments, at least a portion of the outgoing orders are identified based on user input that identifies one or more orders. In some embodiments, the facility may determine that additional pick sequences are not likely to be received based on historical data, and may perform act 303 without applying any generated predicted pick sequences to the digital twin simulation model.

At act 304, the facility identifies an item indicated by one of the indicated pick sequences and identifies attributes of the item based on the pick sequence. In some embodiments, the facility identifies attributes of the item based on data stored in one or more item data repositories that store data indicating attributes for items.

At act 305, the facility identifies a time at which the item is scheduled to be picked in order to be staged for departure from the complex based on the pick sequence. In some embodiments, the facility identifies a range of times based on the scheduled departure of the item. In such embodiments, the range of times may be a pre-selected range of times, determined based on historical data for orders of a similar type to the order from which the pick sequence was generated (such as data indicating that orders received by an entity that is receiving the respective order are more likely to arrive on-time, early, late, etc.), status updates received from the entity receiving the respective order, or other data that may be used to determine a range of times within which an order will depart from a complex.

At act 306, the facility identifies at least one potential storage location for the item based on the simulation data, the time at which the item is scheduled to be picked, and one or more attributes of the item. In some embodiments, the facility uses the simulation data to identify storage locations that have capacity to store the item. In some embodiments, the facility uses the simulation data to identify one or more areas within the complex that will be congested at a time when the item is scheduled to be picked—such as due to other pick sequences, put-away processes, re-slotting processes, or some combination thereof being executed when the item is scheduled to be picked—and uses those identified areas to determine the potential storage location. In some embodiments, to identify the at least one potential storage location, the facility generates a cost of SKU for storing the item at one or more storage locations that have capacity to store the item based on the one or more attributes of the item and the simulation data. The facility may use the cost of SKU to prioritize storage locations for the item that will have capacity to store the item, such that a lower cost of SKU for storing the item at a storage location results in a higher prioritization of the storage location and vice versa. In some embodiments, at act 306, the facility identifies the storage location by determining whether the storage location is an optimal storage location for the item based on the factor of congestion, cost of SKU, attributes of the item, and data describing pick sequences.

In some embodiments, the optimal storage location is a location that reduces the amount of congestion that occurs in an area of the complex when a pick sequence including the item is being executed. For example, if the simulation data indicates that multiple pickers must access the same location at the same time and that special equipment must be used to pick an item at that location such that only one picker can access the location at a time, every other picker that is at the location must wait until they are able to access the location. In another example, an item included in many pick sequences may be stored in a narrow area that only one picker can access at a time. In both of these examples, the facility may determine that the optimal location for at least some of the items stored in those locations is in a different part of the complex in order to reduce the congestion caused in both examples.

In some embodiments, as part of performing act 306, the facility identifies one or more picking containers, such as a cart, bin, pallet, etc., that will be used by entities to perform the pick sequence associated with the item. In such embodiments, the facility may take into account the picking containers when selecting the storage location for the item.

In some embodiments, after act 306, the facility causes one or more entities to move items from their current storage location to the storage locations identified in act 306. In some embodiments, in cases where the facility has determined that an item is already in an optimal storage location, the facility does not cause an entity to move the item to another storage location. In some embodiments, causing one or more entities to move items from their current storage location to the storage locations identified in act 306 comprises transmitting instructions to a computing device associated with an entity to guide the entity to items that are to be moved, guide the entity to new storage locations for items, to indicate to the entity in how the item is to be handled, to indicate an order for moving items to new storage locations, to indicate how the item is to be stored at the new storage location, to indicate one or more other entities that will assist in storing the item at the new storage location, etc.

After act 306, the process ends.

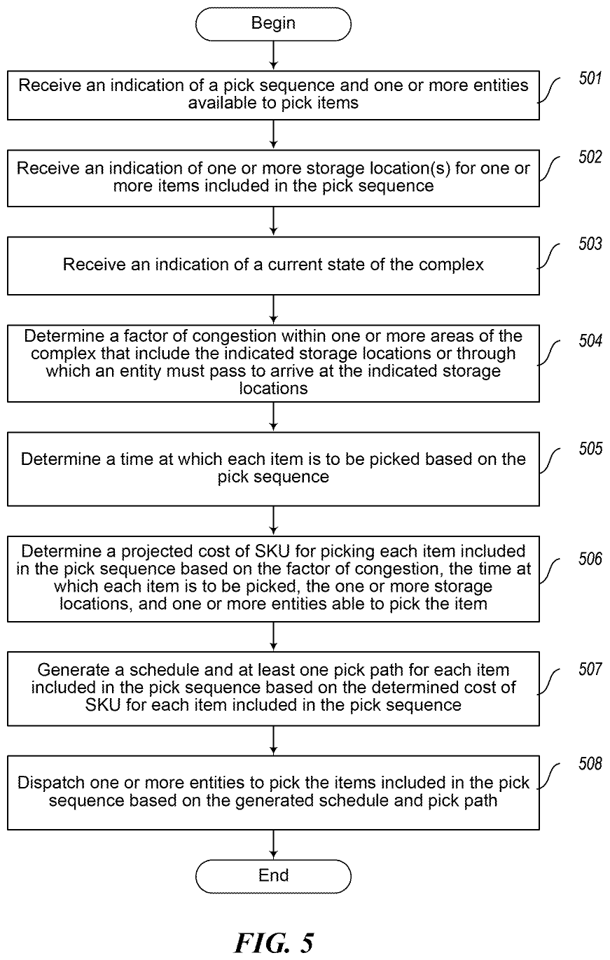

FIG. 5 is a process to dispatch entities to pick items used by the facility in some embodiments. First, at act 501, the facility receives an indication of a pick sequence and that one or more entities are available to pick items. In some embodiments, the facility receives the indication that the entities are available to pick items from a digital twin simulation model of the complex. In some embodiments, the facility receives the indication that the entities are available to pick items from one or more computing devices that have detected, or have received input indicating, the status of the entities.

At act 502, the facility receives an indication of one or more storage locations for the items included in the pick sequence. In some embodiments, at least a portion of the storage locations are determined via a process to identify an alternative storage location for re-slotting an item, such as the process described above in connection with FIG. 3.

At act 503, the facility receives an indication of a current state of the complex. In some embodiments, the facility receives simulation data that includes an indication of the current state of the complex from a digital twin simulation model of the complex. In some embodiments, the facility receives the indication of the current state of the complex from one or more computing devices that detect the current state of an aspect of the complex, receive input regarding the current state of an aspect of the complex, or some combination thereof. A current state of the complex includes one or more of: information regarding storage areas included in the complex, such as a location, capacity, or other attribute regarding a storage area; information regarding one or more entities present in the complex, such as a location, type of entity, current or upcoming task, or other attributes of an entity; a current state of one or more orders arriving at or leaving from the complex; an indication of traffic within the complex; or other attributes of the complex.

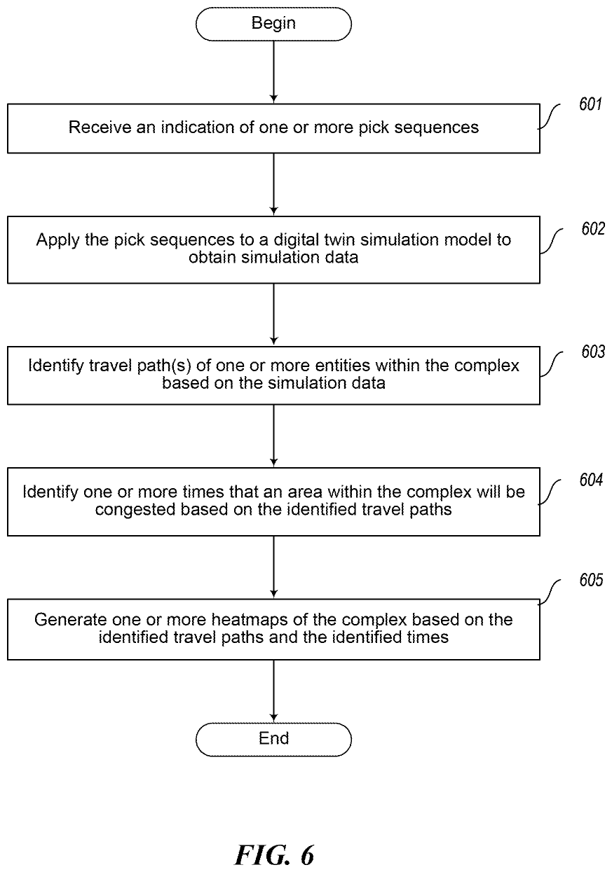

At act 504, the facility determines a factor of congestion within one or more areas of the complex containing the indicated storage locations and through which an entity must pass to arrive at the indicated storage locations. In some embodiments, as part of performing act 504, the facility performs at least a portion of a process to determine congestion within a complex, such as the process described below with respect to FIG. 6. In some embodiments, the facility performs the process described in FIG. 6 before performing act 504, and the facility uses heat maps generated via the process described in FIG. 6 to perform act 504.

FIG. 6 is a flow diagram of a process to identify congestion within a complex used by the facility in some embodiments. First, at act 601, the facility receives an indication of one or more pick sequences. In some embodiments, act 601 is performed in a similar manner to act 301.

At act 602, the facility applies the pick sequences to a digital twin simulation model to obtain simulation data. In some embodiments, act 602 is performed in a similar manner to act 302.

At act 603, the facility identifies one or more travel paths of one or more entities within the complex based on the simulation data. The entities may be entities that move one or more items stored in the complex, that perform picking or put-away operations, or that perform tasks that are not related to moving, storing, or retrieving an item. In some embodiments, the simulation data includes a record of travel paths that entities are predicted to take when the one or more orders arrive or are shipped out of the complex.

At act 604, the facility identifies one or more times that an area within the complex will be congested based on the identified travel paths. In some embodiments, the facility determines, based on the travel paths, when entities are predicted to be within the area and determines that the area will be congested based on whether the number of entities within the area exceeds a threshold amount. In such embodiments, the threshold amount may change based on one or more of: the size of the area, the type of entities traveling through or in the area, whether the entities perform operations or tasks within the area, or other factors related to determining a threshold amount of entities that will cause congestion within the area. In some embodiments, the facility determines a level of congestion of the area based on the number of entities that are predicted to be present in the area. For example, the facility may determine multiple threshold amounts of entities to cause congestion in the area, and for each threshold amount of entities determine whether the congestion in the area is low, medium, high, etc.

In some embodiments, the facility generates one or more predictions of congestion delays based on the level of congestion in the area. A “congestion delay” is a prediction of the amount of additional time an entity will need to travel through an area due to the current level of congestion in the area.

At act 605, the facility generates one or more heatmaps of the complex based on the identified travel paths and the identified times. The heatmaps of the complex indicate whether one or more areas of the complex are congested. In some embodiments, the heatmaps of the complex indicate a level of congestion within the area at one or more times. For example, a heatmap may include a red area that indicates that the area is heavily congested in the morning, but may also indicate that in the afternoon the area has low congestion by changing the heatmap to include a green area in the location of the previously indicated red area.

After act 605, the process to identify congestion within a complex ends. In some embodiments, the facility performs one or more acts described above in connection with FIG. 6 as part of act 306 described above in connection with FIG. 3 in order to use congestion identified in the complex to identify storage locations for an item.

Returning to FIG. 5, at act 505, the facility determines a time at which the item is to be picked based on the pick sequence. In some embodiments, the facility determines the time at which the item is to be picked based on a scheduled time at which the item will depart from the complex.

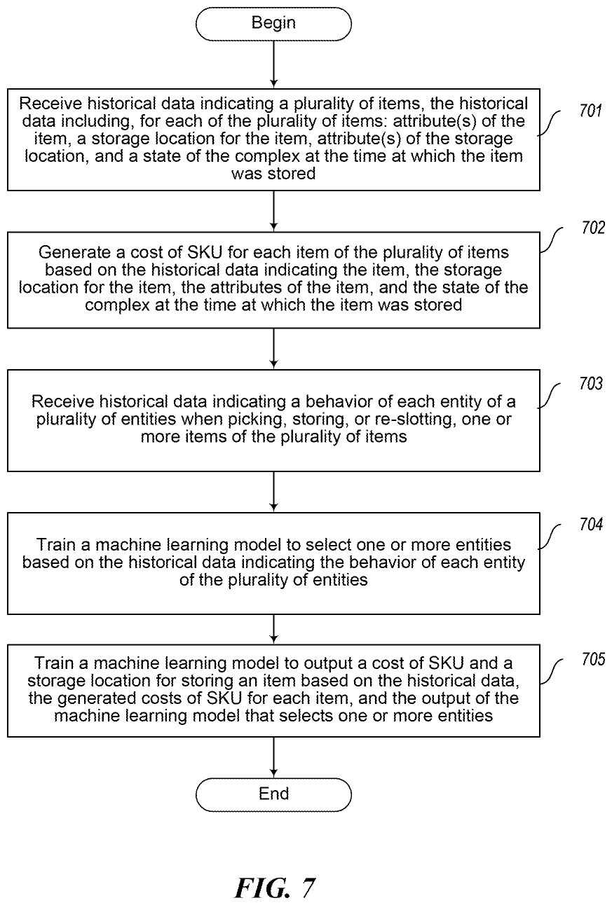

At act 506, the facility determines a projected cost of SKU for picking each item included in the pick sequence. In some embodiments, the facility determines the cost of SKU based on the factor of congestion, the time at which each item is to be picked, the storage locations, and entities available to pick the item. In some embodiments, the facility applies one or more attributes of the item to be picked, one or more storage locations of the item, one or more entities available to pick the item, or some combination thereof to a machine learning model trained to output a cost of SKU based on one or more attributes of an item and a storage location, such as a machine learning model trained via the process described below with respect to FIG. 7.

FIG. 7 is a flow diagram of a process to train a machine learning model to output a projected cost of SKU for picking an item from a location used by the facility in some embodiments. First, at act 701, the facility receives historical data indicating a plurality of items, the historical data including, for each of the plurality of items: one or more attributes of the item, a storage location for the item, one or more attributes of the storage location, and a state of the complex at the time at which the item was stored. In some embodiments, the historical data includes one or more of: a number of orders per hour that include the item or a lead time for the item. In some embodiments, the one or more attributes of the storage location includes one or more of: a number of picking operations at the storage location, such as an average number, a peak number, a number of picking operations that are predicted to be performed during a range of time within which the item arrives at the complex, etc.; an elevation of the location; a depth of the location; an amount of time for an entity to perform picking operations at the storage location; a type of the storage location; an indication of items already stored at the storage location; or other attributes of a storage location.

At act 702, the facility generates a cost of SKU for each respective item of the plurality of items based on the historical data indicating the respective item, the storage location for the respective item, the one or more attributes of the storage location, the one or more attributes for the respective item, and the state of the complex at the time at which the respective item was stored. In some embodiments, the facility generates the cost of SKU by determining the cost to store the item until it departs from the complex, including the costs to move the item to different storage locations within the complex when needed. For example, the facility may take into account: the costs to move an item, including costs incurred by using an entity to move the item; the number of times that the item was moved, such as to another storage location, to be adjusted to store another item at the storage location, to be adjusted such that another item at the storage location can be picked, etc.; the costs for the item to occupy a storage location; the costs of maintaining the storage location, such as maintaining a controlled area (for example, a refrigerated area, humidity controlled area, etc.); or other factors that may be taken into account when generating the cost of SKU.

At act 703, the facility receives historical data indicating a behavior of each of a plurality of entities when picking, storing, re-slotting, or performing other operations regarding one or more items of the plurality of items. The data indicating the behavior of each entity may include: one or more travel speeds of the entity; one or more measures of the time the entity spends picking each type of item; one or more measures of how the use of special equipment effects the amount of time that the entity spends picking items; an indication of the entities picking statistics within one or more areas of the complex; or other data regarding the behavior of an entity.

At act 704, the facility trains an artificial intelligence or machine learning model (the “behavior machine learning model”) to select one or more entities based on the historical data indicating the behavior of each entity of the plurality of entities. In some embodiments, the output of the behavior machine learning model includes one or more of: one or more suggested entities for picking one or more items; one or more costs incurred by one or more entities when picking one or more items; one or more optimal entities for picking one or more items; etc.

At act 705, the facility trains a machine learning model to output a cost of SKU and a storage location for storing an item based on the historical data, the generated cost of SKU for each item, and the output of the behavior machine learning model. In some embodiments, the facility does not use the output of the behavior machine learning model to train the machine learning model that outputs a cost of SKU and storage location. In some embodiments, two machine learning models are used, one that outputs a cost of SKU and one that outputs a storage location. In such embodiments, the facility may employ one of the machine learning models without employing the other, such as to obtain a cost of SKU without obtaining a storage location or vice versa. In an example embodiment, inputs to the machine learning model include one or more of: one or more attributes of the item; a prediction of an amount of time that the item will be stored; one or more potential storage locations; a number of picks at the one or more potential storage locations; an elevation of the one or more potential storage locations; a measure of the time it takes for an entity to pick the item from the one or more storage locations; a time at which the item is predicted to be stored at the one or more storage locations; an indication of the output of the behavior machine learning model for one or more entities available to pick the item; or an indication of whether multiple items of the same type can be carried by an entity at one time. In an example embodiment, the machine learning model outputs a storage location for the item and a predicted cost of SKU for storing the item at the storage area.

After act 705, the process to train a machine learning model to output a cost of SKU for picking an item from a location ends. In some embodiments, the facility collects additional historical data over a selected period of time and uses the additional historical data to re-train the machine learning model. For example, the facility may re-train the machine learning model every month in order to ensure that seasonality of items is taken into account when determining a cost of SKU or storage location. In some embodiments, the machine learning model is continuously re-trained, (for example, re-training the machine learning model every day, week, month, hour, or other time period). In such embodiments, the continuous re-training of the machine learning model allows the machine learning model to continuously learn new behavior of entities in the complex or of constraints for items, entities, etc.

Returning to FIG. 5, at act 507, the facility generates a schedule and at least one pick path for each item included in the pick sequence based on the projected cost of SKU for each item included in the pick sequence. In some embodiments, the facility generates the pick path and schedule such that the congestion within the facility caused by dispatching entities to execute the pick sequence is reduced as much as possible. In such embodiments, the facility may take into account a future state of the complex at the time at which the pick sequence is executed when generating the schedule and at least one pick path. In such embodiments, the facility may obtain the state of the complex from a digital twin simulation model of the complex. In some embodiments, the facility takes into account a time at which orders associated with the pick sequences are scheduled to depart from the facility in order to generate the schedule and pick path.

In some embodiments, the facility generates the schedule and at least one pick path based on the cost of SKU, the factor of the congestion for each storage location, and one or more constraints of each storage location. For example, an item stored at a storage location may require the use of a specific forklift that can reach the top of the storage location. In this example, if the facility determines that the specific forklift is not available based on the state of the complex, it is possible that the facility prevents at least that item in the pick sequence from being picked until the forklift is available.

In some embodiments, the generated schedule includes multiple pick sequences for a single order, such as when the order is large and requires multiple pickers, when the order includes items with various special attributes, etc. For example, an order may include temperature-controlled items and non-temperature-controlled items. The facility may generate multiple pick sequences for this order and schedule the pick sequences such that pick sequences that do not include temperature-controlled items are performed earlier than pick sequences that do include temperature-controlled items. The items included in the pick sequences are gathered into the staging area by entities, and the facility releases the pick sequences in a manner that the temperature-controlled items spend the least amount of time possible in the staging area before being loaded to depart from the complex.

At act 508, the facility dispatches one or more entities to pick items included in the pick sequence based on the generated schedule and pick path. In some embodiments, dispatching an entity includes one or more of: transmitting instructions to a computing device associated with the entity, indicating a path of travel for the entity, indicating a picking order for the entity, indicating one or more other entities that will provide assistance to the entity during the picking operation, indicating whether the entity must transfer one or more items to another entity, or other methods of dispatching an entity to perform a pick operation. In some embodiments, dispatching an entity to perform a pick operation includes transmitting an indication to the entity of how the entity should place the item within a container that the entity uses to carry items. In some embodiments, as part of performing act 508, the facility selects at least entity that is available to perform the pick operations based on the indicated entities received at act 501 and a behavior machine learning model, such as the behavior machine learning model described above in connection with FIG. 7.

After act 508, the process to dispatch entities to pick items ends. In some embodiments, the facility performs the acts 501 to 507 of the process to dispatch entities to pick items in advance to generate an initial schedule that is adjusted based on the current state of the complex. For example, the facility may perform acts 501-507 at the beginning of a day before picking processes begin to create an initial schedule and then adjust the schedule based on a current state of the complex as the picking processes begin, conclude, occur, etc. In some embodiments, the facility uses at least some of acts 501-508 to determine whether an entity should be re-routed within a facility, the pick sequence of the entity should be changed, etc., while the entity is performing pick operations, and to transmit instructions regarding the change in pick sequence to the entity.

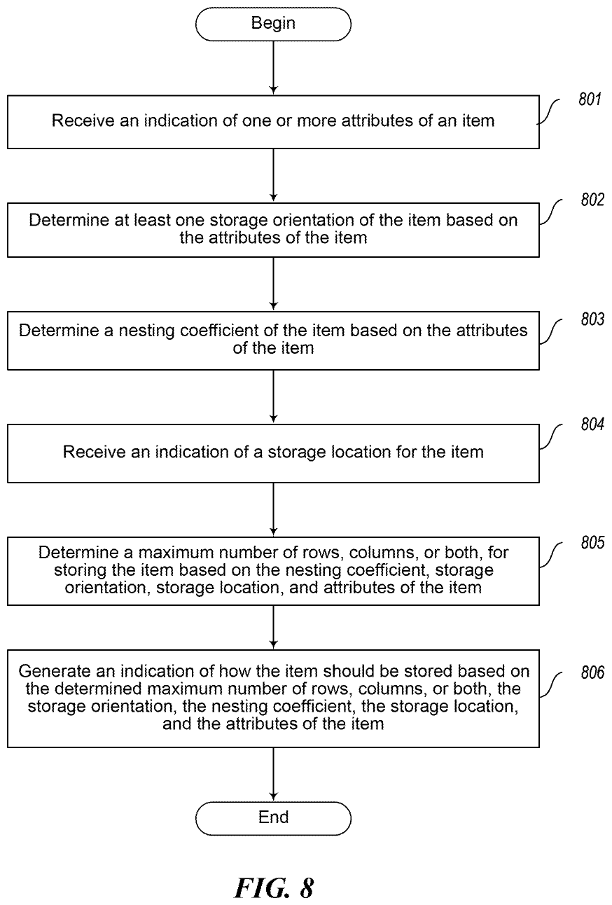

FIG. 8 is a flow diagram of a process to use a nesting coefficient to generate an indication of how an item should be stored in a storage location used by the facility in some embodiments. First, at act 801, the facility receives an indication of one or more attributes of an item. In some embodiments, the item is an item that is currently stored in one storage location, but for which an alternate storage location has been selected, such as via the process to identify an alternative storage location for re-slotting an item described above in connection with FIG. 3.

At act 802, the facility determines at least one storage orientation of the item based on the attributes of the item. For example, the facility may determine that a shape of the item may make the item more susceptible to rolling when it is oriented in a certain way and selects a storage orientation that reduces the chance that the item will roll. In another example, the facility may determine that one or more orientations of the item will damage the item based on the attributes of the item and may select a storage orientation that would not damage the item. In another example, the facility may determine that one or more orientations of the item will result in more items being able to be stored in the storage location than would be possible with other orientations.

At act 803, the facility determines a nesting coefficient of the item based on the one or more attributes of the item.

At act 804, the facility receives an indication of a storage location for the item.

At act 805, the facility determines a maximum number of rows, maximum number of columns, or both for storing the item in the storage location based on the nesting coefficient, storage orientation, storage location, and attributes of the item. For example, the facility may compare the dimensions of the storage location, the dimensions of the items already stored at the storage location, the dimensions of the item to determine the maximum number of rows, columns, or both, for storing the item in the storage location. In some embodiments, the facility applies the nesting coefficient to the dimensions of the item while comparing the dimensions of the item to the dimensions of the storage location and other items stored in the storage location.

At act 806, the facility generates an indication of how the item should be stored based on the determined maximum number of rows and/or columns, the storage orientation, the nesting coefficient, the storage location, and the attributes of the item. In some embodiments, the indication is three-dimensional model generated by the facility. In some embodiments, the indication is transmitted to a computing device associated with an entity that is storing the item.

After act 806, the process to use a nesting coefficient to generate an indication of how an item should be stored in a storage location ends. In some embodiments, the facility uses the process described in FIG. 8 to indicate to an entity how an item is to be stored at the alternative storage location identified during the process to identify an alternative storage location for re-slotting an item described above in connection with FIG. 3.

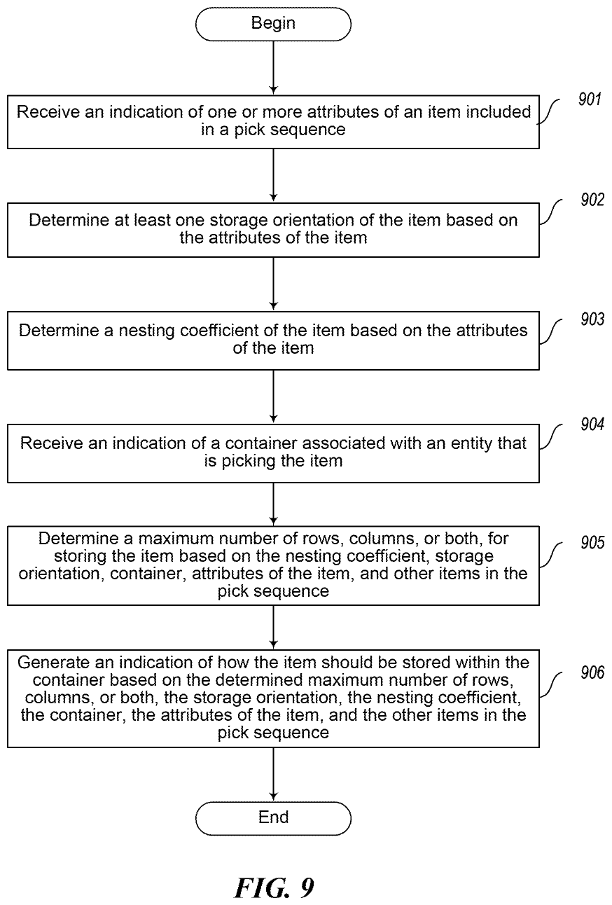

FIG. 9 is a flow diagram of a process to use a nesting coefficient to generate an indication of how an item should be placed in a picking container used by the facility in some embodiments. First, at act 901, the facility receives an indication of one or more attributes of an item included in a pick sequence. In some embodiments, the pick sequence is one for which an entity has been dispatched.

At act 902, the facility determines at least one storage orientation of the item based on the attributes of the item. In some embodiments, the facility performs act 902 in a similar manner to act 802, but with respect to a picking container associated with a picker dispatched to pick the item instead of a storage location.

At act 903, the facility determines a nesting coefficient of the item based on the one or more attributes of the item.

At act 904, the facility receives an indication of a picking container associated with an entity that is picking the item.

At act 905, the facility determines a maximum number of rows, maximum number of columns, or both for placing the item in the picking container based on the nesting coefficient, storage orientation, picking container, and attributes of the item. In some embodiments, the facility performs act 905 in a similar manner to act 805, but with respect to a picking container instead of a storage location, and with respect to other items included in the pick sequence instead of other items stored at a storage location.

At act 906, the facility generates an indication of how the item should be placed in the picking container based on the determined maximum number of rows and/or columns, the storage orientation, the nesting coefficient, the picking container, and the attributes of the item. In some embodiments, the facility performs act 906 in a similar manner to act 806.

After act 806, the process to use a nesting coefficient to generate an indication of how an item should be placed in a picking container ends. In some embodiments, the facility uses the process described in FIG. 9 to indicate to an entity how an item is to be placed in a picking container after the entity has been dispatched to execute a pick sequence, for example, as a result of the completion of the process to dispatch entities to pick items described above in connection with FIG. 5.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. One or more instances of computer-readable media collectively having contents configured to cause a computing device to perform a method for picking items, the method comprising:
at a first time:
receiving an indication of one or more orders, each order indicating a time at which at least one item stored at a complex is scheduled to leave the complex;
generating, based on the one or more orders, one or more pick sequences;
obtaining simulation data by applying the one or more pick sequences to a digital twin simulation of a complex, the simulation data indicating one or more predicted states of the complex during the process of picking items based on the one or more pick sequences; and
for each of one or more items stored at the complex, identifying an alternative storage location to which to transfer the item based on the simulation data; and
at a second time later than the first time:
receiving, via the digital twin simulation of the complex, data indicating a current state of the complex; and
identifying a pick sequence, based on the data indicating the current state of the complex, the one or more pick sequences, and alternative storage locations to which at least a portion of the one or more items were transferred.

2. The one or more instances of computer-readable media of claim 1, wherein obtaining the simulation data further comprises:
receiving historical data describing a number of past orders;
predicting, based on the indicated one or more orders and the historical data, whether one or more additional orders will be received by the complex within a predetermined time period;
generating one or more additional pick sequences based on the prediction that one or more additional orders will be received by the complex; and
applying the one or more additional pick sequences to the digital twin simulation of the complex.

3. The one or more instances of computer-readable media of claim 1, wherein identifying the one or more alternative storage locations further comprises:
obtaining an indication of a plurality of resource costs for storing the one or more items at each storage location from a plurality of locations by applying a machine learning model configured to output a resource cost for storing an item at a storage location to one or more attributes of the one or more items and the simulation data; and
identifying the one or more alternative storage locations from the plurality of storage locations based on the indicated resource costs for storing the item at each storage location and the simulation data.

4. The one or more instances of computer-readable media of claim 1, wherein the method further comprises:
causing one or more entities to move the at least a portion of the one or more items to the one or more alternative storage locations.

5. The one or more instances of computer-readable media of claim 4, wherein causing one or more entities to move the at least a portion of the one or more items to the one or more alternative storage locations further comprises:
for each respective item of the one or more items:
identifying a computing device associated with an entity that is moving the respective item to an alternative storage location; and
causing the computing device to display an indication of how the respective item is to be stored at the alternative storage location.

6. The one or more instances of computer-readable media of claim 1, wherein the method further comprises:
causing an entity to pick items included in the identified pick sequence.

7. The one or more instances of computer-readable media of claim 6, wherein causing an entity to pick the items included in the identified pick sequence further comprises:
obtaining an indication of one or more entities available to pick the items included in the identified pick sequence by applying a machine learning model configured to output an indication of one or more entities to pick items included in a pick sequence based on historical picking behavior data of the one or more entities and the pick sequence; and
selecting the entity to pick the items included in the identified pick sequence based on the indicated one or more entities and the simulation data.

8. The one or more instances of computer-readable media of claim 6, wherein causing an entity to pick the items included in the identified pick sequence further comprises:
for each respective item included in the identified pick sequence:
identifying a computing device associated with the entity; and
causing the computing device to display an indication of how the respective item is to be placed in a container associated with the entity.

9. One or more storage devices storing an item slotting and picking data structure, the data structure comprising:
information specifying one or more pick sequences, each pick sequence including one or more items and one or more times at which the one or more items are scheduled to leave a complex;
information specifying one or more forecasted states of the complex during the process of picking items included in the one or more pick sequences;
information specifying one or more alternative storage locations for at least one item; and
information specifying a current state of the complex,
such that the one or more pick sequences are usable to obtain the one or more forecasted states of the complex,
the one or more forecasted states of the complex are usable to identify the one or more alternative storage locations, and
the one or more pick sequence and the current state of the complex are usable to identify a pick sequence for an entity.

10. The one or more storage devices of claim 9, the data structure further comprising:
information specifying historical data describing a number of orders including a time at which at least one item is scheduled to leave the complex were received by the complex in the past,
such that the information specifying the historical data are usable to predict whether one or more additional orders will be received by the complex within a predetermined time period.

11. The one or more storage devices of claim 9, the data structure further comprising:
information specifying one or more entities associated with the complex,
such that the one or more entities are able to be caused to execute the one or more pick sequences, and
the one or more entities are able to be caused to move one or more items to the one or more alternative storage locations.

12. The one or more storage devices of claim 9, the data structure further comprising:
information specifying a state of a machine learning model configured to output a resource cost based on one or more attributes of an item and a forecasted state of the complex,
such that the forecasted states of the complex and one or more attributes of one or more items included in a pick sequence are able to be applied to the machine learning model to obtain one or more resource costs for a plurality of storage locations, and
the one or more alternative storage locations are able to be identified based on the one or more resource costs for the plurality of storage locations and the forecasted states of the complex.

13. A system comprising:
a computing device configured to:
receive an indication of one or more pick sequences, each pick sequence indicating at least one item stored at a complex and a time at which the at least one item is scheduled to leave the complex;
obtain simulation data by applying the one or more pick sequences to a digital twin simulation of a complex, the simulation data indicating one or more predicted states of the complex during the process of picking items based on the one or more pick sequences;
for each of one or more items stored at the complex, identify an alternative storage location to which to transfer the item based on the simulation data;
receive, via the digital twin simulation of the complex, data indicating a current state of the complex; and
identify a pick sequence, based on the data indicating the current state of the complex, the one or more pick sequences, and alternative storage locations to which at least a portion of the one or more items were transferred.

14. The system of claim 13, wherein, to obtain the simulation data, the computing system is further configured to:
receive historical data describing a number of past pick sequences;
predict, based on the indicated one or more pick sequences and the historical data, whether one or more additional pick sequences will be executed within the complex within a predetermined time period; and
apply the prediction of the one or more additional pick sequences to the digital twin simulation of the complex.

15. The system of claim 13, wherein, to identify the one or more alternative storage locations, the computing system is further configured to:
obtain an indication of a plurality of resource costs for storing the one or more items at each storage location from a plurality of locations by applying a machine learning model configured to output a resource cost for storing an item at a storage location to one or more attributes of the one or more items and the simulation data; and
identify the one or more alternative storage locations from the plurality of storage locations based on the indicated resource costs for storing the item at each storage location and the simulation data.

16. The system of claim 13, wherein the computing system is further configured to:
cause one or more entities to move the at least a portion of the one or more items to the one or more alternative storage locations.

17. The system of claim 16, wherein to cause one or more entities to move the at least a portion of the one or more items to the one or more alternative storage locations, the computing device is further configured to:
for each respective item of the one or more items:
identify a display device associated with an entity that is moving the respective item to an alternative storage location; and
cause the display device to display an indication of how the respective item is to be stored at the alternative storage location.

18. The system of claim 13, wherein the computing device is further configured to:
cause an entity to pick items included in the identified pick sequence.

19. The system of claim 18, wherein to cause the entity to pick items included in the identified pick sequence, the computing device is further configured to:
obtain an indication of one or more entities available to pick the items included in the identified pick sequence by applying a machine learning model configured to output an indication of one or more entities to pick items included in a pick sequence based on historical picking behavior data of the one or more entities and the pick sequence; and
select the entity to pick the items included in the identified pick sequence based on the indicated one or more entities and the simulation data.

20. The system of claim 18, wherein to cause the entity to pick items included in the identified pick sequence, the computing device is further configured to:
for each respective item included in the identified pick sequence:
identify a display device associated with the entity; and
cause the display device to display an indication of how the respective item is to be placed in a container associated with the entity.
